(19) United States
(12) Patent Application Publication
(10) Pub. No.: US 2025/0054548 A1
(43) Pub. Date: Feb. 13, 2025

(54) NON-VOLATILE 1-BIT STATE STORAGE AND BISTABLE SOLID-STATE RELAY INCLUDING THE SAME

(71) Applicant: Liebherr-Electronics and Drives GmbH, Lindau (DE)

(72) Inventors: Lars Hummel, Wangen (DE); Andreas TRÖBERSBERGER, Scheidegg (DE); Michael Rose, Lindenberg (DE); Cornelius Fink, Langen bei Bregenz (AT)

(21) Appl. No.: 18/799,423

(22) Filed: Aug. 9, 2024

(30) Foreign Application Priority Data
Aug. 10, 2023 (DE) 10 2023 121 434.9

(51) Int. Cl. G11C 16/10; H03M 1/66

(52) U.S. Cl. CPC G11C 16/10; H03M 1/66

(57) ABSTRACT

A non-volatile 1-bit state storage including a first signal converter for converting a digital input signal into an analog intermediate signal and a second signal converter for converting the analog intermediate signal into a digital output signal. The first signal converter is provided with a non-volatile memory so that after an outage of a power supply voltage, the previously output analogue intermediate signal is restored. A bistable solid-state relay that assumes a bistable switching state by means of the non-volatile 1-bit state storage and restores this state after an outage of the power supply voltage.

### CROSS-REFERENCE TO RELATED APPLICATIONS

This application claims benefit under 35 USC § 119 of DE Application No. 10 2023 121 434.9 filed 10 Aug. 2023, which is incorporated herein by reference in its entirety as if set forth herein.

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### SEQUENCE LISTING

Not Applicable

### STATEMENT REGARDING PRIOR DISCLOSURES BY THE INVENTOR OR A JOINT INVENTOR

Not Applicable

### BACKGROUND OF THE DISCLOSURE

### 1. Field of the Invention

The present invention relates to a non-volatile 1-bit state storage and a bistable solid-state relay with such a non-volatile 1-bit state storage.

### 2. Description of Related Art

Non-volatile 1-bit state storage devices are components in digital systems and are required for a wide range of applications. The advantage of a non-volatile 1-bit state storage is that in the event of an outage of the power supply voltage, the previously assumed initial state is stored and can be assumed again when the supply voltage is restored.

Implementations of such a non-volatile 1-bit state storage on the market rely on complex hardware based on a microcontroller in conjunction with a non-volatile memory, for example EEPROM.

A less complex, yet for aviation applications very expensive and very prone to errors, implementation from the state of the art teaches the magnetic storage of the state of the 1-bit state storage using permanent magnets (as used in bistable mechanical relays), so that the state assumed before a supply voltage failure can be resumed when the supply voltage returns.

The aim of the invention is to provide a non-volatile 1-bit state storage that can be implemented using simple commercially available components (COTS or Commercial Off-The-Shelf) and does not have to interact with a complex component such as a microcontroller (with corresponding complex control software). Such 1-bit state storage is not only cheaper than conventional implementations, but also comprises a significantly lower level of complexity, which leads to higher reliability.

### BRIEF SUMMARY OF THE INVENTION

This object is achieved by a non-stable 1-bit state storage comprising a signal converter, in particular a digital-to-analog (D/A) converter, for converting a digital input signal into an analog output signal, and a bistable signal converter, in particular a bistable multivibrator, the input of which is connected to the analog output signal of the signal converter, wherein the signal converter is provided with a non-volatile memory, so that after an outage of the power supply voltage, the previously output analog output signal is again applied to the output of the signal converter. In addition, the present invention claims a bistable semiconductor relay comprising the non-volatile 1-bit state storage. There is also indicated a method for operating a non-volatile 1-bit state storage or a non-volatile bistable semiconductor relay is also given.

According to the invention, it is provided that the non-volatile 1-bit state storage comprises a first signal converter, in particular a digital-to-analog (D/A) converter, for converting a digital input signal into an analog output signal, and a bistable signal converter, in particular a bistable multivibrator, the input of which is connected to the analog output signal of the signal converter, wherein the first signal converter is provided with a non-volatile memory so that after an outage of the power supply voltage the previously output analog output signal is again applied to the output of the signal converter.

By interconnecting the first signal converter with the bistable signal converter, a non-volatile 1-bit state storage is achieved, which results from two standard electronic components.

In this respect, to operate the 1-bit state storage, a digital signal value is first sent to the first signal converter, where it is converted into a corresponding analog value. This analog value, usually a resistance or voltage value, is then fed to the input of a bistable signal converter so that it outputs either a logical 1 (e.g., supply voltage, Vcc) or a logical 0 (e.g., ground level) at its output.

As the first signal converter has a non-volatile memory which, in the event of a supply voltage failure, ensures that the (digital) input signal transmitted thereto before the failure is stored, the input signal stored there can be accessed after the supply voltage returns so that the state prior to a supply voltage failure can be restored.

The highlight of the present invention is that the generation of a non-volatile 1-bit state storage does not require any of the complex implementations on the market with a microcontroller or mechanical implementation with internal permanent magnets, but instead combines two components that are widely used in electronics. In this respect, it initially seems contradictory to convert a digital signal, namely the input signal given to the first signal converter, into an analog signal and then convert it again into a digital output signal (using the bistable signal converter). However, the combination of these two components is equal in its function to the much more complex and expensive solutions available on the market but is also much cheaper and more reliable.

According to an optional modification of the present invention, it may be provided that the signal converter for converting a digital input signal into an analog output signal is a digital potentiometer.

A rather rare term for a digital potentiometer is resistive digital-to-analog converter, which already refers to the ability of the digital potentiometer to convert a digital input signal into an analog output signal.

A digital potentiometer is a type of electronic device that performs the same basic function as a conventional (analog) potentiometer but is controlled digitally.

An analog potentiometer is a three-terminal resistor with a sliding or rotating contact that determines the division value of the resistor. By rotating or sliding the contact, the resistance along the potentiometer can be changed, allowing it to be used to adjust electrical signals such as volume, brightness and so on.

A digital potentiometer works in a similar way, but instead of using a mechanical element to adjust the resistance, it uses digital signals to do so. It typically has three important terminals: the two ends of the resistor (also: potentiometer end terminals) and the moving contact (usually referred to as the “wiper” or “center tap”).

The digital input signal sent to the signal converter is therefore connected to the digital potentiometer in such a way that it controls the movement of the center tap. With a corresponding connection of the digital potentiometer as a voltage divider, a corresponding analog voltage is then applied to the center tap depending on the digital input signal. At a maximal value of the digital input signal, the center tap is connected to the upper potentiometer end terminal, so that the maximum analog voltage (e.g., Vcc of the digital potentiometer) is applied to the center tap. In the opposite case, i.e., when a minimum value of the digital input signal is input to the channel for controlling the center tap of the digital potentiometer, the center tap is shifted accordingly so that it is connected to the lower potentiometer end terminal. This is typically connected to ground so that a minimum analog voltage is applied to the center tap. The input digital signal is therefore converted into a corresponding analog voltage.

Alternatively, the potentiometer can be connected as a single two-pole variable resistor with an external additional resistor to form a voltage divider, creating a potentiometer again.

As an alternative to a potentiometer, via whose resistor outputs an output voltage is applied by connecting a supply voltage, a signal converter with voltage output can be used.

If the supply voltage to the signal converter should now fail, the non-volatile memory of the digital potentiometer ensures that the last input signal that was input to the digital potentiometer before an outage of the power supply voltage is stored so that it can be processed immediately after the supply voltage returns, thus restoring the last state before the supply voltage failed.

The use of a digital potentiometer as the first signal converter is advantageous in particular because digital potentiometers with a non-volatile memory, which stores the last digital control signal entered, have good market availability and have already proven themselves over a longer period of time.

As already briefly explained above, according to the present invention it may advantageously be provided that a center tap, i.e., the variably adjustable output of the digital potentiometer, is the output of the first signal converter.

In this respect, when using the digital potentiometer as the first signal converter, it is particularly advantageous if it is connected as a voltage divider, as described above. In this respect, a higher voltage is applied to the upper potentiometer end terminal than to the lower potentiometer end terminal, so that the center tap has a specific voltage value depending on the position. In particular, it can be advantageous if, for example, a supply voltage (Vcc) is connected to the upper potentiometer end terminal and earth is connected to the lower potentiometer end terminal. Those skilled in the art are aware, however, that the functionality of the digital potentiometer as the first voltage converter is actually only dependent on a difference in the voltage value at the two potentiometer end connections.

Nevertheless, it can presumably be regarded as a rule that—in accordance with an advantageous modification of the present invention—the digital potentiometer is connected with its upper potentiometer end terminal to the supply voltage and/or with its lower potentiometer end terminal to earth. This is simply because the supply voltage is readily available as a “high” voltage, just like the ground.

According to an optional modification of the present invention, it may be provided that the first signal converter for converting a digital input signal into an analog output signal is a digital-to-analog converter.

To implement the basic idea of the present invention, it is sufficient if the digital input signal of the first signal converter is given to a digital-to-analog converter. The output of such a digital-to-analog converter assumes an analog voltage level corresponding to the digital input signal, so that a high voltage is output when the value of a digital input signal is high, and a low voltage is output when the value of the digital input signal is low.

The use of a digital-to-analog converter as the first signal converter is advantageous because these components also have a high market availability, and there are also inexpensive implementations that comprise the required non-volatile memory function, so that after a supply voltage failure the last digital input signal input can be processed immediately after the supply voltage returns, so that the analog output signal output before the supply voltage failure can be output again without the need for renewed control via the input signal.

According to an advantageous implementation of the present invention, it may be provided that the output of the bistable signal converter outputs the state of the non-volatile 1-bit state storage. A bistable signal converter, also known as a bistable multivibrator or threshold switch, is a type of circuit that has two stable states. It can change from one state to the other and remain in that state until the input signal causes it to change state.

According to the present invention, the input of the bistable signal converter is connected to the output of the first signal converter (e.g., implemented by the digital potentiometer or the digital-to-analog converter) and causes the output of the bistable signal converter to be set to logical 1 or logical 0. Which of the two states the bistable signal converter outputs depends on whether the analog (voltage) signal applied to the input is above a threshold value or below this threshold value. In this respect, it is evident to those skilled in the art that the logical value 0 or the logical value 1—depending on the wiring of the bistable signal converter-corresponds, for example, to ground or Vcc.

Therefore, according to the invention, it may be provided that the bistable signal converter is configured to set the output to logical 1 when a threshold value of an input signal applied to the input is exceeded and to set the output to logical 0 when a or the threshold value of the input signal applied to the input is undershot.

Advantageously, according to the invention, it can be provided that the bistable signal converter is a Schmitt trigger. This ensures the conversion of a constantly changing input signal into an output signal with two fixed states, namely “high” and “low”.

The decisive advantage of a Schmitt trigger lies in its hysteresis. Hysteresis refers to the different threshold values that are set for the change between the two states. If the input signal exceeds a certain high threshold value (the so-called upper threshold), the output signal changes to logical 1 (high). It remains at logical 1 even if the input signal falls below this high threshold value, as long as it does not fall below a lower threshold value (the so-called lower threshold). Only then is the output signal output as logical zero (low). This mechanism prevents rapid or unwanted changes in the input signal from causing the output signal to flutter.

Therefore, according to the present invention, it may advantageously be provided that the Schmitt trigger comprises a first threshold value for the change of the output signal to logical 1 and a second threshold value different from the first threshold value for the change of the output signal to logical 0, the first threshold value being spaced upwards from a center of a voltage range which can be applied to the input of the Schmitt trigger and the second threshold value being spaced downwards from a center of a voltage range which can be applied to the input of the Schmitt trigger, preferably in such a way that any change of any bit due to a bit error in the digital input signal of the signal converter or of the non-volatile memory does not lead to a change of the output signal at the Schmitt trigger.

In this respect, it may be provided that the upper threshold value is in the upper third, preferably in the upper quarter, and the lower threshold value is in the lower third, preferably in the lower quarter, of the detectable voltage range.

The upper threshold value (first threshold value) and the lower threshold value (second threshold value) are spaced so far apart that the random and unwanted “flipping” of a single bit in the digital input signal of the signal converter does not cause the Schmitt trigger to change its output state, provided that a correspondingly high digital input value or a correspondingly low digital input value is used for the signal converter.

This is advantageous in particular because so-called single-event upsets can occur when using the non-volatile 1-bit state storage in the aviation sector, which cause the random “flipping” of a bit in a bitstream.

A single event upset (SEU) is a phenomenon that occurs primarily in aerospace applications but can also be observed in other high-power environments. It refers to a change in the state or behavior of an electronic component or system caused by a single, high-energy particle. These particles can originate from the natural radiation environment and occur in particular at high altitudes or in space, where radiation levels are higher than on the Earth's surface.

When such a particle hits a semiconductor in an electronic component, it can deposit enough energy to change the state of a bit in a memory device, causing it to flip, also known as a bit flip. Such bit flip events can lead to errors in data processing, which can be potentially dangerous, in particular in safety-critical systems such as aircraft. Precisely to counteract this effect, the Schmitt trigger together with the signal converter can be configured in such a way that the unintentional change of a single bit in the digital input signal of the signal converter does not lead to a change in the output state of the Schmitt trigger.

According to an advantageous implementation of the present invention, it may be provided that the signal converter and the bistable signal converter are each implemented by a separate logic chip, in particular by an integrated circuit.

Combining these two separate components then forms the claimed non-volatile 1-bit state storage, which is otherwise only available on the market in very complex designs or at very high prices. The present invention avoids these disadvantages by simply combining these components and thus achieves comparable functionality at significantly lower cost and better robustness.

The invention further comprises a bistable solid-state relay comprising a non-volatile 1-bit state storage according to one of the foregoing claims, and a semiconductor relay having a switching input connected to the output of the bistable signal converter for actuating the switching function of the relay.

A solid-state relay (SSR), also known as a semiconductor relay, is a type of relay that uses semiconductor technology to perform a switching function. Unlike conventional electromechanical relays, which use a mechanical switching action, solid-state relays rely on semiconductor devices such as transistors, thyristors or triacs to control the flow of current.

A typical solid-state relay comprises four main terminals: two for the control voltage (input) and two for the load (output). One possible implementation here is that the input is coupled to an LED which, when energized, generates a light signal that activates a light-sensitive semiconductor circuit on the output side of the relay. This circuit opens or closes the current path for the connected load depending on whether light is emitted from the LED or not.

The invention further relates to a method for operating a non-volatile 1-bit state storage according to one of the foregoing aspects or the bistable solid-state relay described above, wherein as input signal to the 1-bit state storage there is transmitted a value in the upper half, preferably upper third, more preferably upper quarter, of the digital input signal range which can be received by the signal converter for the output of a logical 1 at the output 11 of the bistable multivibrator, or as input signal to the 1-bit state storage there is transmitted a value in the lower half, preferably lower third, preferably lower quarter, of the digital input signal range which can be received by the signal converter for the output of a logical 0 at the output 11 of the bistable multivibrator.

Furthermore, according to an advantageous modification of the method, it can be provided that, when implementing the bistable multivibrator as a Schmitt trigger, the upper threshold value and the lower threshold value are spaced apart from one another in such a way that, in the event of an unwanted “flipping” of a bit in the input signal of the signal converter, the output signal of the Schmitt trigger does not change. For example, it may be provided that the upper threshold value is in the upper third, preferably upper quarter, of the entire voltage range that can be detected by the Schmitt trigger, and the lower threshold value is in the lower third, preferably lower quarter, of the entire voltage range that can be detected by the Schmitt trigger. If the digital input signal is selected accordingly, even a 2-bit error tolerance is then possible, which can compensate for the unwanted flipping of 2 bits in the digital input signal.

Furthermore, according to an optional modification of the method, it may be provided that a maximal value of the digital input signal range that can be received by the signal converter is transmitted as an input signal to the 1-bit state storage for outputting a logical 1 at the output 11 of the bistable multivibrator, or that a minimal value of the digital input signal range that can be received by the signal converter is transmitted as an input signal to the 1-bit state storage for outputting a logical 0 at the output 11 of the bistable signal converter.

This ensures that, in the worst-case scenario, a single bit in the bitstream of the digital input signal of the signal converter or in the memory of the non-volatile memory only results in the signal that is then passed to the signal converter or further processed from the non-volatile memory being a value that applies approximately in the middle of the digital input signal range of the signal converter.

Assuming, for example, that the input signal comprises 8 bits, the input signal range extends from 0-255, as a bit sequence from [0000 0000] to [1111 1111] is possible. The worst case for the flipping of a single bit is the bit with the highest significance, also known as MSB (for Most Significant Bit).

If the byte actually stored in the memory or entered via the input signal is [0000 0000] and is unintentionally changed by a single event upset to [1000 0000], this corresponds to a decimal value of 128. Conversely, the worst-case scenario for a bit flip is for a byte [1111 1111] to become the sequence [0111 111], which corresponds to a decimal value of 127. If you now set the Schmitt trigger so that its upper threshold is above a voltage value that is output by the signal converter when it receives an input signal in the form [1000 0000] and its lower threshold is below a voltage value, which is output by the signal converter when it receives an input signal in the form [0111 1111], a 1-bit error tolerance is created if (in the present example) either the bit sequence [1111 1111] or [0000 0000] is used as the input signal to control the Non-volatile 1-bit state storage.

Those skilled in the art understand that a correspondingly greater distance between the lower threshold and the upper threshold of the Schmitt trigger can also improve fault tolerance.

The invention further relates to a vehicle, in particular an aircraft, having a non-volatile 1-bit state storage according to one of the aspects described above or a bistable solid-state relay also described above.

In an exemplary embodiment of the present invention, a non-volatile 1-bit state storage comprises a signal converter configured to convert digital input signals into analog output signals comprising an input configured to input the digital input signals, an output configured to output the analog output signals, and non-volatile memory for storing a current digital input signal of the digital input signals, and a bistable signal converter comprising an input in signal communication with the output of the signal converter, wherein after an interruption of a power supply voltage to the storage, the current digital input signal is again applied to the input of the signal converter.

In any exemplary embodiment of the present invention, the output of the bistable signal converter can be a state of the non-volatile 1-bit state storage.

In any exemplary embodiment of the present invention, the output of the bistable signal converter can be configured to a logical 1 when a threshold value of the input analog output signal is exceeded, and a logical 0 when the threshold value of the input analog output signal is undershot.

In any exemplary embodiment of the present invention, the signal converter can be a digital-to-analog (D/A) converter.

In any exemplary embodiment of the present invention, the bistable signal converter can be a bistable multivibrator.

In any exemplary embodiment of the present invention, the signal converter and the bistable signal converter can each be implemented by a separate logic chip.

In any exemplary embodiment of the present invention, the signal converter can comprise a digital potentiometer.

In any exemplary embodiment of the present invention, the bistable signal converter can be a Schmitt trigger.

In any exemplary embodiment of the present invention, the output of the signal converter can comprise a center tap of the digital potentiometer.

In any exemplary embodiment of the present invention, the digital potentiometer can be connected as a voltage divider.

In any exemplary embodiment of the present invention, the digital potentiometer is at least one of connected to the power supply voltage by an upper potentiometer end terminal or ground-connected by a lower potentiometer end terminal.

In any exemplary embodiment of the present invention, the output of the Schmitt trigger is configured to a logical 1 when a first threshold value of the input analog output signal is exceeded, and a logical 0 when a second threshold value of the input analog output signal is undershot, wherein the first threshold value is spaced upwards from a center of a voltage range that can be applied to the input of the Schmitt trigger, and wherein the second threshold value is spaced downwards from the center of the voltage range that can be applied to the input of the Schmitt trigger.

In any exemplary embodiment of the present invention, the Schmitt trigger can be configured such that any change of any bit due to a bit error in the digital input signal of the signal converter or of the non-volatile memory does not lead to a change of the output of the Schmitt trigger.

In another exemplary embodiment of the present invention, a bistable solid-state relay comprises any of the exemplary non-volatile 1-bit state storages, and a semiconductor relay, wherein a switching input of semiconductor relay is connected to an output of the bistable signal converter to actuate a switching function of the semiconductor relay.

In another exemplary embodiment of the present invention, a method comprises inputting the digital input signals to any of the exemplary non-volatile 1-bit state storages, and outputting either a logical 1 or a logical 0 from the bistable signal converter, wherein values of the inputted digital input signals are each in a first range of a value range of the digital input signals that result in the output of the bistable signal converter of the logical 1, and wherein the values of the inputted digital input signals are each in a second range of the value range of the digital input signals that result in the output of the bistable signal converter of the logical 0.

In another exemplary embodiment of the present invention, a method comprises inputting the digital input signals to any of the exemplary bistable solid-state relays, and outputting either a logical 1 or a logical 0 from the bistable signal converter, wherein values of the inputted digital input signals are each in a first range of a value range of the digital input signals that result in the output of the bistable signal converter of the logical 1, and wherein the values of the inputted digital input signals are each in a second range of the value range of the digital input signals that result in the output of the bistable signal converter of the logical 0.

In any exemplary embodiment of the present invention, the first range can be an upper half, and the second range can be a lower half.

In any exemplary embodiment of the present invention, the first range can be an upper third, and the second range can be a lower third.

In any exemplary embodiment of the present invention, the first range can be an upper quarter, and the second range cam be a lower quarter.

In any exemplary embodiment of the present invention, the first range can be a maximal value, and the second range can be a minimal value.

In another exemplary embodiment of the present invention, a vehicle comprises any of the exemplary non-volatile 1-bit state storages.

In another exemplary embodiment of the present invention, a vehicle comprises any of the exemplary the bistable solid-state relays.

In any exemplary embodiment of the present invention, the vehicle can be an aircraft.

These and other objects, features and advantages of the present invention will become more apparent upon reading the following specification in conjunction with the accompanying drawing figures.

### BRIEF DESCRIPTION OF THE DRAWINGS

The accompanying Figures, which are incorporated in and constitute a part of this specification, illustrate several aspects described below.

FIG. 1 is a schematic representation of an embodiment of a 1-bit state storage.

FIG. 2 is a schematic representation of an embodiment of a bistable semiconductor relay with 1-bit state storage.

### DETAIL DESCRIPTION OF THE INVENTION

To facilitate an understanding of the principles and features of the various embodiments of the invention, various illustrative embodiments are explained below. Although exemplary embodiments of the invention are explained in detail, it is to be understood that other embodiments are contemplated. Accordingly, it is not intended that the invention is limited in its scope to the details of construction and arrangement of components set forth in the following description or illustrated in the drawings. The invention is capable of other embodiments and of being practiced or carried out in various ways. Also, in describing the exemplary embodiments, specific terminology will be resorted to for the sake of clarity.

It must also be noted that, as used in the specification and the appended claims, the singular forms “a,” “an” and “the” include plural references unless the context clearly dictates otherwise. For example, reference to a component is intended also to include composition of a plurality of components. References to a composition containing “a” constituent is intended to include other constituents in addition to the one named.

Also, in describing the exemplary embodiments, terminology will be resorted to for the sake of clarity. It is intended that each term contemplates its broadest meaning as understood by those skilled in the art and includes all technical equivalents which operate in a similar manner to accomplish a similar purpose.

Ranges may be expressed herein as from “about” or “approximately” or “substantially” one particular value and/or to “about” or “approximately” or “substantially” another particular value. When such a range is expressed, other exemplary embodiments include from the one particular value and/or to the other particular value.

Similarly, as used herein, “substantially free” of something, or “substantially pure”, and like characterizations, can include both being “at least substantially free” of something, or “at least substantially pure”, and being “completely free” of something, or “completely pure”.

By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

It is also to be understood that the mention of one or more method steps does not preclude the presence of additional method steps or intervening method steps between those steps expressly identified. Similarly, it is also to be understood that the mention of one or more components in a composition does not preclude the presence of additional components than those expressly identified.

The materials described as making up the various elements of the invention are intended to be illustrative and not restrictive. Many suitable materials that would perform the same or a similar function as the materials described herein are intended to be embraced within the scope of the invention. Such other materials not described herein can include, but are not limited to, for example, materials that are developed after the time of the development of the invention.

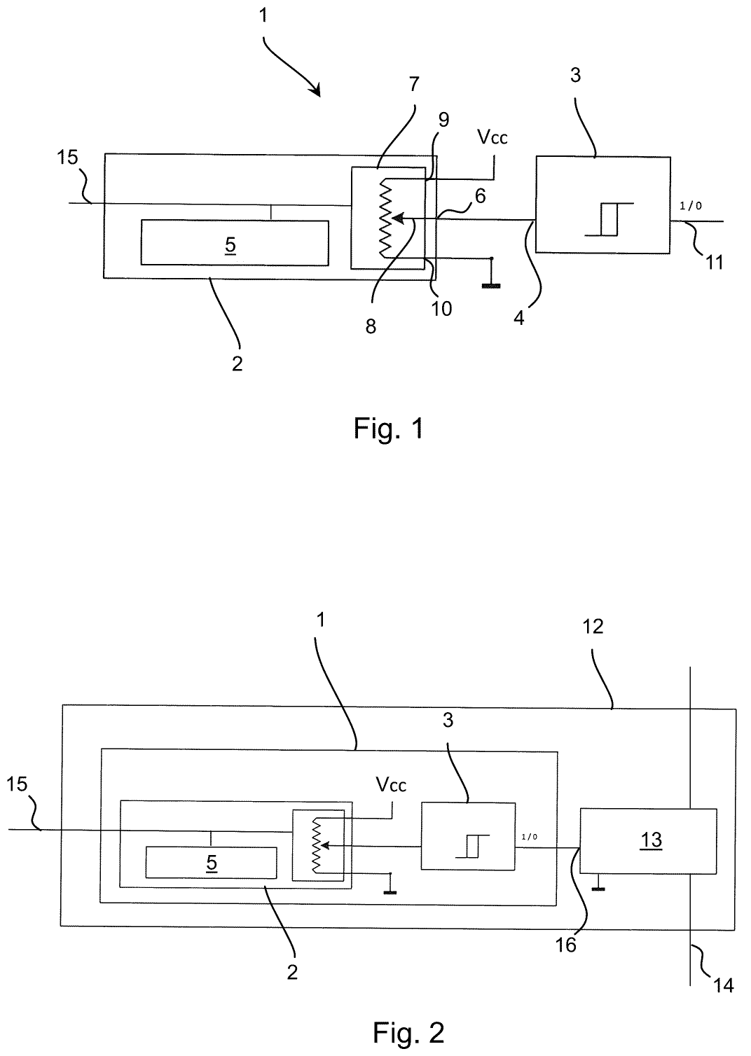

FIG. 1 shows a schematic representation of an embodiment of a 1-bit state storage device 1. A signal converter 2 for converting a digital input signal into an analog output signal can be seen, which has a digital potentiometer 7 that has a non-volatile memory 5. The digital potentiometer 7 has a resistor which is arranged between the upper potentiometer end terminal 9 and the lower potentiometer end terminal 10. The center tap 8 is adjustable so that it is moved via the resistor arranged between the two potentiometer end terminals depending on the control signal of the digital potentiometer 7. The position of the center tap 8 is defined by the input power 15. The non-volatile memory 5 stores the digital signal that causes the center tap to move via the input power 15, so that even in the event of a temporary supply voltage failure, the state that was set before the supply voltage failure can be immediately restored.

In FIG. 1, the upper potentiometer end terminal 9 is coupled to the supply voltage and the lower potentiometer end terminal 10 is coupled to earth, so that the digital potentiometer 7 is connected as a voltage divider. Depending on the position of the center tap 8, an analog voltage corresponding to the setting is applied to the output 6 of the signal converter 2, which—as already explained—can be varied by the digital input signal, which is input via the input power 15.

The output of the signal converter 6 is connected to the input 4 of the bistable signal converter 3, so that depending on the analog voltage value at the input of the bistable signal converter 3, either logical 1 or logical 0 is output at the output 11 of the bistable signal converter 3. In this case, there can be undertaken a simple threshold value comparison, which performs a comparison of the analog voltage value at the input 4 of the bistable signal converter 3 and, depending thereon, controls the output 11 of the bistable signal converter 3.

When using a Schmitt trigger, there is no simple threshold value comparison of the analog voltage value input to the Schmitt trigger 3, but instead there is an upper threshold and a lower threshold, wherein switching to logical 1 occurs when the upper threshold is exceeded and switching to logical 0 occurs when the lower threshold is undershot. This is advantageous in particular if the input signal is noisy, as if there is only one threshold value, the output signal may change frequently when the threshold value is crossed.

FIG. 1 therefore shows the realization of a non-volatile 1-bit state storage, which has been implemented using simple standard components, so-called “Commercial-Off-The-Shelf” parts.

The memory state “1” is set, for example, by setting the digital potentiometer to its maximal value. This is done by transmitting a corresponding digital signal via input channel 15. The entire supply voltage (for example 3.3 V) is applied to the bistable signal converter, in particular the Schmitt trigger 3, which thereby outputs logical 1. The memory state “0” is achieved, for example, by setting the variable digital potentiometer to its minimum value. As a result, the ground (for example 0 V) is applied to the bistable signal converter 3, in particular the Schmitt trigger, so that it outputs a logical 0.

Since the position of the center tap 8 is stored in the potentiometer 7 by the internal and non-volatile memory 5, the position of the center tap 8 remains at the previously stored value even after an outage of the power supply voltage. Together with the bistable signal converter 3, which acts like a digitizer, a digital value, either 0 or 1, is thus stored.

FIG. 2 shows an illustration of a bistable semiconductor relay 12, in which the 1-bit state storage 1 shown in FIG. 1 takes over the control of the semiconductor relay 13.

The reference sign 14 shows the line switchable by the semiconductor relay 13, which is switched depending on the input 16 of the semiconductor relay 13. Those skilled in the art understand that there is a plurality of possible implementations of the semiconductor relay 13, so that no specific definition is provided here. However, one possibility is to use an LED that is connected to the input 16 of the semiconductor relay 13 and emits light at a level of logical 1. Relay 13 then connects line 14 when light is emitted by the LED, and this is usually done by means of light-sensitive transistors.

FIG. 2 therefore shows a solid-state relay 12 that is very simple in its structure and yet generated using known components, which is significantly cheaper and simpler in design compared to conventional implementations. Thus, it uses neither a microprocessor nor internal permanent magnets.

### LIST OF REFERENCE SIGNS

1 1-bit state storage.
2 signal converter (digital potentiometer with internal non-volatile memory).
3 bistable signal converter.
4 input of the bistable signal converter.
5 non-volatile memory.
6 output of the signal converter.
7 digital potentiometer (without internal non-volatile memory).
8 center tap of the digital potentiometer.
9 upper potentiometer end terminal.
10 lower potentiometer end terminal.
11 output of the bistable signal converter.
12 bistable solid-state relay.
13 semiconductor relay.
14 line switchable by the relay.
15 Input line to 1-bit state storage.
16 Input of the semiconductor relay.

Numerous characteristics and advantages have been set forth in the foregoing description, together with details of structure and function. While the invention has been disclosed in several forms, it will be apparent to those skilled in the art that many modifications, additions, and deletions, especially in matters of shape, size, and arrangement of parts, can be made therein without departing from the spirit and scope of the invention and its equivalents as set forth in the following claims. Therefore, other modifications or embodiments as may be suggested by the teachings herein are particularly reserved as they fall within the breadth and scope of the claims here appended.

What is claimed is:

1. A non-volatile 1-bit state storage comprising:
a signal converter configured to convert digital input signals into analog output signals comprising:
an input configured to input the digital input signals;
an output configured to output the analog output signals; and
non-volatile memory for storing a current digital input signal of the digital input signals; and
a bistable signal converter comprising an input in signal communication with the output of the signal converter;
wherein after an interruption of a power supply voltage to the storage, the current digital input signal is again applied to the input of the signal converter.

2. The non-volatile 1-bit state storage of claim 1, wherein an output of the bistable signal converter is a state of the non-volatile 1-bit state storage.

3. The non-volatile 1-bit state storage of claim 1, wherein an output of the bistable signal converter is configured to:
a logical 1 when a threshold value of the input analog output signal is exceeded; and
a logical 0 when the threshold value of the input analog output signal is undershot.

4. The non-volatile 1-bit state storage of claim 1, wherein:
the signal converter is a digital-to-analog (D/A) converter; and
the bistable signal converter is a bistable multivibrator.

5. The non-volatile 1-bit state storage of claim 1, wherein the signal converter and the bistable signal converter are each implemented by a separate logic chip.

6. The non-volatile 1-bit state storage of claim 1, wherein the signal converter comprises a digital potentiometer.

7. The non-volatile 1-bit state storage of claim 1, wherein the bistable signal converter is a Schmitt trigger.

8. The non-volatile 1-bit state storage of claim 6, wherein the output of the signal converter comprises a center tap of the digital potentiometer.

9. The non-volatile 1-bit state storage of claim 6, wherein the digital potentiometer is connected as a voltage divider.

10. The non-volatile 1-bit state storage of claim 6, wherein the digital potentiometer is at least one of:
connected to the power supply voltage by an upper potentiometer end terminal; or
ground-connected by a lower potentiometer end terminal.

11. The non-volatile 1-bit state storage of claim 7, wherein the Schmitt trigger;
wherein an output of the Schmitt trigger is configured to:
a logical 1 when a first threshold value of the input analog output signal is exceeded; and
a logical 0 when a second threshold value of the input analog output signal is undershot,
wherein the first threshold value is spaced upwards from a center of a voltage range that can be applied to the input of the Schmitt trigger; and
wherein the second threshold value is spaced downwards from the center of the voltage range that can be applied to the input of the Schmitt trigger.

12. The non-volatile 1-bit state storage of claim 11, wherein the Schmitt trigger is configured such that any change of any bit due to a bit error in the digital input signal of the signal converter or of the non-volatile memory does not lead to a change of the output of the Schmitt trigger.

13. A bistable solid-state relay comprising:
the volatile 1-bit state storage according to claim 1; and
a semiconductor relay;
wherein a switching input of semiconductor relay is connected to an output of the bistable signal converter to actuate a switching function of the semiconductor relay.

14. A method comprising:
inputting the digital input signals to the non-volatile 1-bit state storage of claim 1; and
outputting either a logical 1 or a logical 0 from the bistable signal converter;
wherein values of the inputted digital input signals are each in a first range of a value range of the digital input signals that result in the output of the bistable signal converter of the logical 1; and
wherein the values of the inputted digital input signals are each in a second range of the value range of the digital input signals that result in the output of the bistable signal converter of the logical 0.

15. A method comprising:
inputting the digital input signals to the bistable solid-state relay of claim 13; and
outputting either a logical 1 or a logical 0 from the bistable signal converter;
wherein values of the inputted digital input signals are each in a first range of a value range of the digital input signals that result in the output of the bistable signal converter of the logical 1; and
wherein the values of the inputted digital input signals are each in a second range of the value range of the digital input signals that result in the output of the bistable signal converter of the logical 0.

16. The method of claim 14, wherein:
the first range is an upper half; and
the second range is a lower half.

17. The method of claim 14, wherein:
the first range is an upper third; and
the second range is a lower third.

18. The method of claim 14, wherein:
the first range is an upper quarter; and
the second range is a lower quarter.

19. The method of claim 14, wherein:
the first range is a maximal value; and
the second range is a minimal value.

20. The method of claim 15, wherein:
the first range is an upper half; and
the second range is a lower half.

21. The method of claim 15, wherein:
the first range is an upper third; and
the second range is a lower third.

22. The method of claim 15, wherein:
the first range is an upper quarter; and
the second range is a lower quarter.

23. The method of claim 15, wherein:
the first range is a maximal value; and
the second range is a minimal value.

24. A vehicle comprising:
the non-volatile 1-bit state storage according to claim 1.

25. The vehicle of claim 24, wherein the vehicle is an aircraft.

26. A vehicle comprising:
the bistable solid-state relay of claim 13.

27. The vehicle of claim 26, wherein the vehicle is an aircraft.
